(19) United States
(12) Patent Application Publication
(10) Pub. No.: US 2019/0306981 A1
(43) Pub. Date: Oct. 3, 2019

(54) CIRCUIT SUBSTRATE AND METHOD FOR FABRICATING CIRCUIT SUBSTRATE

(71) Applicant: FUJITSU LIMITED, Kawasaki-shi (JP)

(72) Inventors: Masaharu Furuyama, Fujisawa (JP); Daisuke Mizutani, Sagamihara (JP); Tomoyuki AKAHOSHI, Atsugi (JP)

(73) Assignee: FUJITSU LIMITED, Kawasaki-shi (JP)

(21) Appl. No.: 16/263,041

(22) Filed: Jan. 31, 2019

(30) Foreign Application Priority Data
Mar. 30, 2018 (JP) 2018-068804

(51) Int. Cl. H05K 1/16; H05K 1/11; H05K 1/02; H05K 3/46; H05K 3/34

(52) U.S. Cl. CPC H05K 1/162; H05K 1/115; H05K 3/341; H05K 3/4602; H05K 1/0298

(57) ABSTRACT

A circuit substrate includes a first insulating layer, a capacitor disposed over the first insulating layer, the capacitor including a dielectric layer, a first conductor layer disposed on a first face of the dielectric layer, and a second conductor layer disposed on a second face opposite to the first face of the dielectric layer and having an electric resistivity higher than that of the first conductor layer, a third conductor layer disposed on a surface of the second conductor layer, the third conductor layer having an electric resistivity lower than that of the second conductor layer, a second insulating layer covering the capacitor, and a conductor via disposed in the second insulating layer, the conductor via being coupled to a portion of the third conductor layer.

### CROSS-REFERENCE TO RELATED APPLICATION

This application is based upon and claims the benefit of priority of the prior Japanese Patent Application No. 2018-68804, filed on Mar. 30, 2018, the entire contents of which are incorporated herein by reference.

### FIELD

The embodiments discussed herein are related to a circuit substrate and a method for fabricating the circuit substrate.

### BACKGROUND

There is a technique of incorporating a capacitor in a circuit substrate. The capacitor is set to have a structure for a dielectric layer formed therein using a given material to be sandwiched by a pair of conductor layers therebetween.

For example, there is a technique according to which a dielectric layer is formed by printing a dielectric material on a surface of an inner layer circuit, a metal layer is formed by printing a copper paste on a surface of the dielectric layer, a hole is formed by applying a laser beam to an insulating layer disposed on the above layers, and a plating material layer is formed by applying an electroless copper plating process to the hole. Moreover, there is another technique according to which a high dielectric-constant material sheet including a copper foil to be one of the electrodes of a capacitor is stacked on a surface of an inner layer circuit board on which the other of the electrodes of the capacitor is formed, laser beam drilling is conducted for an insulating layer that is disposed on the stacked layers, and an electroless copper plating layer is formed to form an outer layer circuit.

Relating to the above, as to a capacitor incorporated in a circuit substrate, of its conductor layers sandwiching its dielectric layer, the one conductor layer may use therein a material whose electric resistivity is high compared to that of the other. When another conductor such as a conductor via is coupled to the conductor layer that uses therein the material whose electric resistivity is high, the electric resistance therebetween is relatively high and the performance of the circuit substrate incorporating the capacitor may be degraded.

The followings are reference documents.
[Document 1] Japanese Laid-open Patent Publication No. 5-218660 and
[Document 2] Japanese Laid-open Patent Publication No. 2004-103617.

### SUMMARY

According to an aspect of the embodiments, a circuit substrate includes a first insulating layer, a capacitor disposed over the first insulating layer, the capacitor including a dielectric layer, a first conductor layer disposed on a first face of the dielectric layer, and a second conductor layer disposed on a second face opposite to the first face of the dielectric layer and having an electric resistivity higher than that of the first conductor layer, a third conductor layer disposed on a surface of the second conductor layer, the third conductor layer having an electric resistivity lower than that of the second conductor layer, a second insulating layer covering the capacitor, and a conductor via disposed in the second insulating layer, the conductor via being coupled to a portion of the third conductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram depicting an example of a circuit substrate according to a first embodiment;

FIG. 2 is a diagram depicting another example of a circuit substrate;

FIG. 3 is a diagram depicting an example of arrangement of a conductor layer on an electrode of a capacitor and a conductor via coupled to the conductor layer;

FIGS. 4A and 4B are diagrams depicting another example of an arrangement of a conductor layer on an electrode of a capacitor and a conductor via coupled to the conductor layer;

FIG. 5 is a diagram depicting an example of a configuration of a circuit substrate;

FIGS. 6A and 6B are diagrams (Part I) explaining an evaluation of a resistance component;

FIG. 7 is a diagram (Part II) explaining an evaluation of a resistance component;

FIG. 8 is a graph explaining an evaluation of a power source noise;

FIGS. 9A to 9D are diagrams (Part I) explaining an evaluation of an influence exerted by an area of a conductor layer on properties;

FIGS. 10A and 10B are diagrams (Part II) explaining an evaluation of an influence exerted by an area of a conductor layer on properties;

FIGS. 11A to 11D are diagrams (Part I) explaining an evaluation of an influence exerted by a thickness of a conductor layer on properties;

FIGS. 12A and 12B are diagrams (Part II) explaining an evaluation of an influence exerted by a thickness of a conductor layer on properties;

FIGS. 13A and 13B are diagrams (Part I) depicting an example of a method for forming a circuit substrate according to a second embodiment;

FIG. 14 is a diagram (Part II) depicting an example of a method for forming a circuit substrate according to the second embodiment;

FIG. 15 is a diagram (Part III) depicting an example of a method for forming a circuit substrate according to the second embodiment;

FIG. 16 is a diagram (Part IV) depicting an example of a method for forming a circuit substrate according to the second embodiment;

FIG. 17 is a diagram (Part V) depicting an example of a method for forming a circuit substrate according to the second embodiment;

FIG. 18 is a diagram (Part VI) depicting an example of a method for forming a circuit substrate according to the second embodiment;

FIG. 19 is a diagram (Part VII) depicting an example of a method for forming a circuit substrate according to the second embodiment;

FIG. 20 is a diagram (Part VIII) depicting an example of a method for forming a circuit substrate according to the second embodiment;

FIG. 21 is a diagram depicting an example of a circuit substrate according to a third embodiment;

FIG. 22 is a diagram depicting an example of a circuit substrate according to a fourth embodiment; and

FIG. 23 is a diagram explaining an electronic apparatus according to a fifth embodiment.

### DESCRIPTION OF EMBODIMENTS

Embodiments will be described below with reference to the drawings.

### First Embodiment

Improvement for higher performance, a higher operation speed, a larger current, and a lower voltage has recently been advanced for semiconductor devices such as semiconductor chips, semiconductor packages, and the like that are mounted on electronic devices and electronic apparatuses. For the stable operation of each of these semiconductor devices, it is important to suppress any fluctuation of the power source voltage and to remove any power source noise (also referred to as “high frequency noise” or “high frequency power source noise”). Reduction of the impedance is therefore demanded to any circuit substrate that has the semiconductor device mounted thereon.

An approach is known as one of the approaches to reduce the impedance, according to which a chip capacitor is mounted on a circuit substrate and the chip capacitor is coupled between the power source line and the ground (GND) line of the circuit substrate. Moreover, other approaches are known according to one of which a chip capacitor is incorporated in a circuit substrate from the viewpoint that the inductance component of the wire is suppressed by reducing the length of the wire from the semiconductor device to the capacitor, and according to one of which a capacitor formed by a dielectric layer and a pair of conductor layers sandwiching the dielectric layer therebetween (a thin film capacitor) is incorporated.

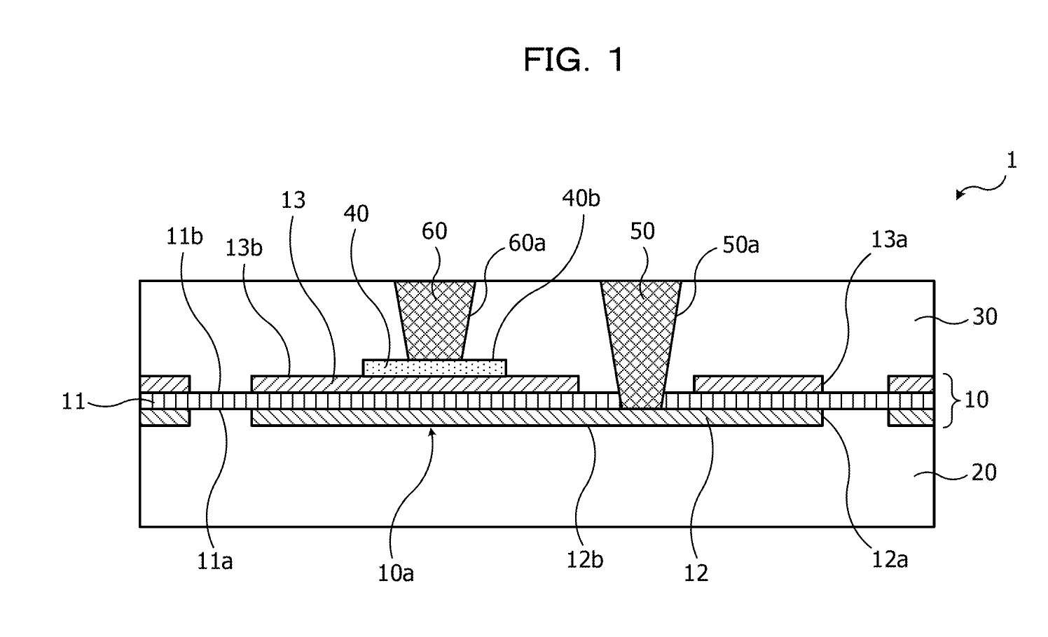

FIG. 1 is a diagram depicting an example of a circuit substrate according to a first embodiment. FIG. 1 schematically depicts a cross-sectional view of the essential portion of the example of the circuit substrate.

The circuit substrate 1 depicted in FIG. 1 is an example of a capacitor-incorporated circuit substrate. A circuit substrate 1 includes a capacitor 10, an insulating layer 20, an insulating layer 30, a conductor layer 40, a conductor via 50, and a conductor via 60.

The capacitor 10 includes a dielectric layer 11, an electrode (a conductor layer) 12 disposed on one face 11a of the dielectric layer 11, and an electrode (a conductor layer) 13 disposed on an other face 11b of the dielectric layer 11. As above, the capacitor 10 has a structure for the dielectric layer 11 to be sandwiched by a pair of the electrode 12 and the electrode 13 therebetween.

Any one of various dielectric materials is used in the dielectric layer 11. For example, a ceramic material is used in the dielectric layer 11. Any one of various high dielectric materials such as barium titanate (BaTiO₃: BTO) is usable as the ceramic material of the dielectric layer 11. Any one of various high dielectric materials is also usable as the ceramic material of the dielectric layer 11, such as barium strontium titanate (BaₓSr₁₋ₓTiO₃: BSTO) produced by adding strontium (Sr) to BTO, strontium titanate (SrTiO₃: STO), lead zirconate titanate (Pb(Zr,Ti)O₃: PZT), or PZT added with lanthanum (La) (PLZT). The thickness of the dielectric layer 11 is set to be, for example, 1 to 3 μm.

Any one of various conductor materials is used in the electrode 12 and the electrode 13. For example, a metal material is used in the electrode 12 and the electrode 13. Copper (Cu), nickel (Ni), or the like is usable as the metal material of the electrode 12 and the electrode 13. For example, in the circuit substrate 1, Cu that is one of the conductor materials each having a relatively low electric resistivity is used in the electrode 12, and Ni that is one of the conductor materials each having a relatively high electric resistivity is used in the electrode 13. The thicknesses of the electrode 12 and the electrode 13 are each set to be, for example, 15 to 30 μm. The electrode 12 and the electrode 13 are each set to have a given planar shape. The electrode 12 and the electrode 13 respectively have an opening 12a and an opening 13a disposed therein.

The conductor layer 40 is disposed on the electrode 13 (a surface 13b thereof) of the capacitor 10. Any one of various conductor materials each having an electric resistivity lower than that of the electrode 13 to which the conductor layer 40 is coupled is used in the conductor layer 40. For example, a metal material is used in the conductor layer 40. In addition to Cu, gold (Au), silver (Ag), aluminum (Al), or the like is usable as the metal material for the conductor layer 40. The conductor layer 40 is disposed on, for example, a portion of the electrode 13 of the capacitor 10. In addition to this, the conductor layer 40 may be disposed on the overall electrode 13 of the capacitor 10. The conductor layer 40 is set to have a given thickness and a given planar shape such as a circular shape or a rectangular shape in the planar view.

The insulating layer 20 and the insulating layer 30 are disposed to cover a substrate 10a (the top face and the bottom face thereof) that includes the capacitor 10 and the conductor layer 40 disposed on the electrode 13 of the capacitor 10.

The insulating layer 20 is disposed on the side of the electrode 12 (a surface 12b thereof) of the capacitor 10. The insulating layer 20 is an insulating layer that is disposed on a base substrate including wires in one layer or plural layers and that includes a resin, a prepreg, or the like. A resin material such as an epoxy resin, a polyimide resin, or a bismaleimide triazine resin, or any one of these resin materials each including a fiber such as glass or the like, or cloth is usable in the insulating layer 20.

The insulating layer 30 is disposed on the side of the electrode 13 (the surface 13b thereof) of the capacitor 10 and the conductor layer 40 (a surface 40b thereof). Similarly to the insulating layer 20, a resin material such as an epoxy resin, a polyimide resin, or a bismaleimide triazine resin, or any one of these resin materials each including a fiber such as glass or the like, or cloth is usable for the insulating layer 30.

The conductor via 50 and the conductor via 60 penetrate the insulating layer 30 and are disposed to respectively be electrically coupled to the electrode 12 and the electrode 13 of the capacitor 10. The conductor via 50 and the electrode 13 of the capacitor 10 are electrically isolated from each other. The conductor via 60 and the electrode 12 of the capacitor 10 are electrically isolated from each other. Any one of various conductor materials is used in each of the conductor via 50 and the conductor via 60. For example, a metal material is used in each of the conductor via 50 and the conductor via 60. Cu or the like is usable as the metal material of the conductor via 50 and the conductor via 60.

The conductor via 50 electrically coupled to the electrode 12 of the capacitor 10 is disposed at a position that corresponds to (the position that overlaps with) that of the opening 13a disposed in the electrode 13 of the capacitor 10, of the insulating layer 30. The conductor via 50 penetrates the insulating layer 30, further penetrates the dielectric layer 11 of the capacitor 10, and is directly coupled to the electrode 12 of the capacitor 10.

The conductor via 60 electrically coupled to the electrode 13 of the capacitor 10 is disposed at a position that corresponds to (a position that overlaps with) that of the conductor layer 40 disposed on the electrode 13 of the capacitor 10, of the insulating layer 30. The conductor via 60 penetrates the insulating layer 30 and is directly coupled to the conductor layer 40 on the electrode 13 of the capacitor 10. The conductor via 60 is coupled to a portion of the conductor layer 40. To complete this coupling, the diameter of the conductor via 60 (the diameter of the part (the lower end) coupled to the conductor layer 40) is set, or the planar size, the planar shape, and the planar arrangement of the conductor layer 40 to which the conductor via 60 is coupled are set.

The conductor via 50 and the conductor via 60 are formed as filled vias that are obtained by filling an opening 50a and an opening 60a to respectively have the conductor via 50 and the conductor via 60 disposed therein, with a conductor material. In addition, the conductor via 50 and the conductor via 60 may be formed as conformal vias that are obtained by forming a conductor material layer on each of the inner walls of the opening 50a and the opening 60a to respectively have the conductor via 50 and the conductor via 60 disposed therein, and the inside of each of these conformal vias may be filled with a resin.

As above, in the circuit substrate 1, the conductor layer 40 having the electric resistivity lower than that of the electrode 13 of the capacitor 10 is disposed on the electrode 13, and the conductor via 60 is coupled to the conductor layer 40. Any increase of the resistance component between the conductor via 60 and the capacitor 10 is thereby suppressed even when a conductor material having the relatively high electric resistivity is used in the electrode 13 of the capacitor 10.

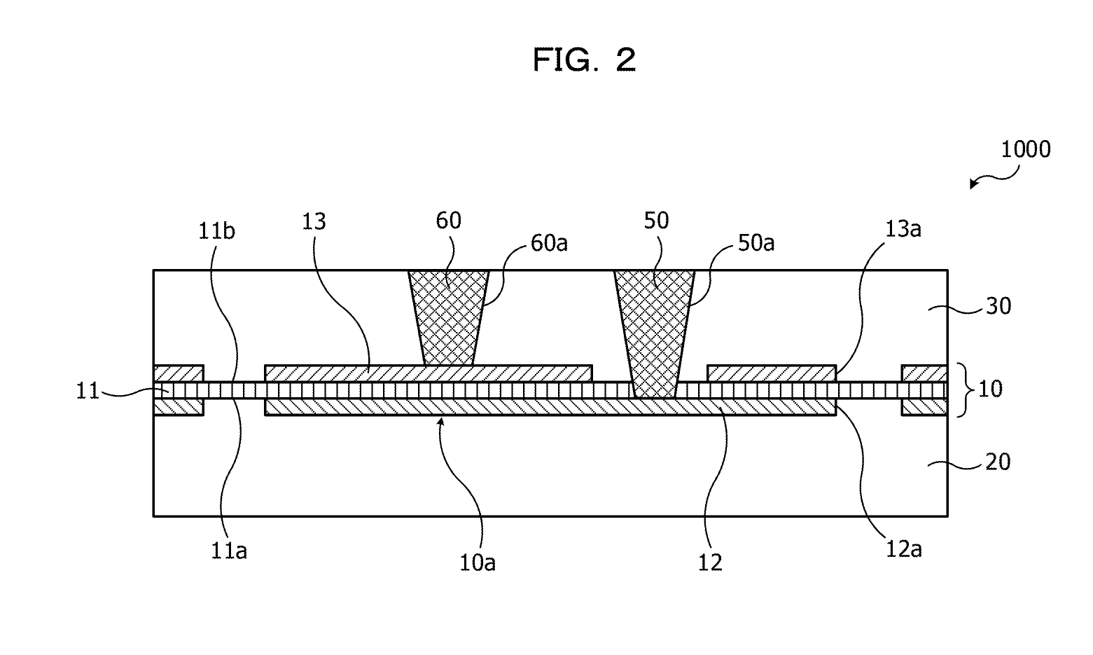

Concerning the above, for comparison, another example of the circuit substrate is depicted in FIG. 2.

A circuit substrate 1000 depicted in FIG. 2 differs from the circuit substrate 1 depicted in FIG. 1 above in that the circuit substrate 1000 has a configuration for the above conductor layer 40 not to be disposed on the electrode 13 of the capacitor 10 and for the conductor via 60 to directly be coupled to the electrode 13.

For forming the capacitor 10, for example, a method is used according to which a dielectric material layer is formed on the electrode 13, the dielectric layer 11 is formed by conducting thermal treatment for the dielectric material layer, and the electrode 12 is formed on the dielectric layer 11. In the case where the thermal treatment is conducted for the dielectric material layer at a high temperature, it is demanded to the electrode 13 to be the base bed for the dielectric material that the material of the electrode 13 is a thermally stable material. For example, Ni is therefore used taking into consideration the cost, the fabrication easiness, and the like in addition to the thermal stability.

However, when the conductor material such as Ni of the electrode 13 has an electric resistivity that is higher than that of the conductor material such as Cu of the conductor via 60 to be coupled to the electrode 13, the resistance component between the electrode 13 and the conductor via 60 becomes large in the circuit substrate 1000 as depicted in FIG. 2 and an increase of the impedance is caused. When the impedance is increased, in the circuit substrate 1000, the reduction effect for the power source noise by the capacitor 10 thereof may not sufficiently be obtained.

In contrast, in the circuit substrate 1 depicted in FIG. 1 above, the conductor layer 40 having the electric resistivity lower than that of the electrode 13 of the capacitor 10 is disposed on the electrode 13 and the conductor via 60 is coupled to the conductor layer 40. The resistance component between the electrode 13 and the conductor via 60 may thereby be reduced, the impedance may thereby be reduced, and the reduction effect for the power source noise may be enhanced even when the conductor material having the relatively high electric resistivity such as Ni is used in the electrode 13 of the capacitor 10. The circuit substrate 1 having an excellent power source noise reduction effect is realized by the above configuration.

The conductor layer 40 disposed on the electrode 13 of the capacitor 10 is set to have a planar size that is larger than that of a lower end of the conductor via 60 to be coupled to the conductor layer 40.

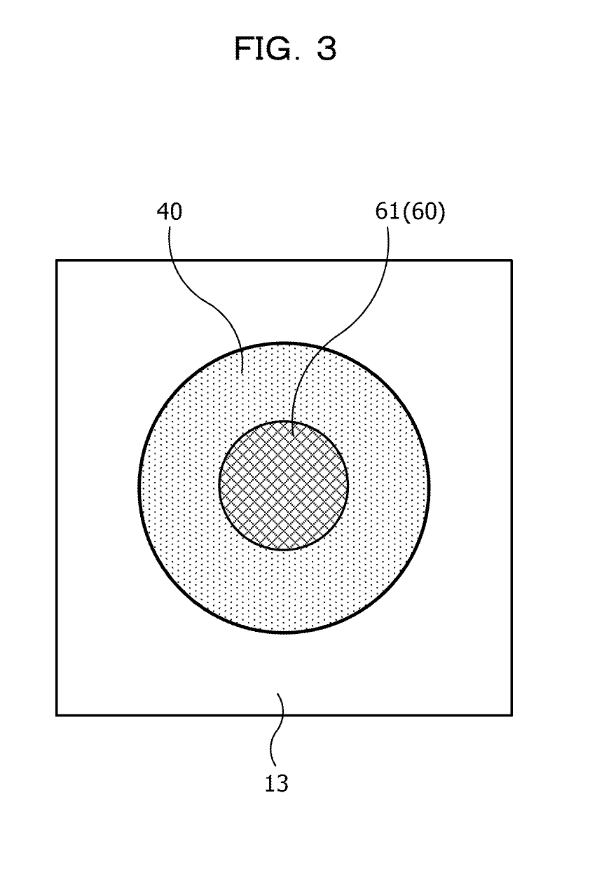

FIG. 3 is a diagram depicting an example of arrangement of a conductor layer on an electrode of a capacitor and a conductor via coupled to the conductor layer. FIG. 3 schematically depicts the planar arrangement of the electrode, the conductor layer on the electrode, and the lower end of the conductor via coupled to the conductor layer.

For example, as depicted in FIG. 3, the conductor layer 40 is disposed at a planar size that is smaller than that of the electrode 13, on the electrode 13 of the capacitor 10. For example, as depicted in FIG. 3, the conductor layer 40 is set to have a circular shape in the planar view. The lower end 61 of the conductor via 60 is coupled to a portion of the conductor layer 40. The conductor layer 40 is disposed on the electrode 13 of the capacitor 10 to have a planar size that is larger than that of the lower end 61 of the conductor via 60. The conductor via 60 is electrically coupled to the electrode 13 through the conductor layer 40 having the planar size that is larger than that of the lower end 61 of the conductor via 60 as above, and the resistance component is thereby reduced and the reduction of the impedance is facilitated compared to the case where the lower end 61 is directly coupled to the electrode 13 without the conductor layer 40 present therebetween.

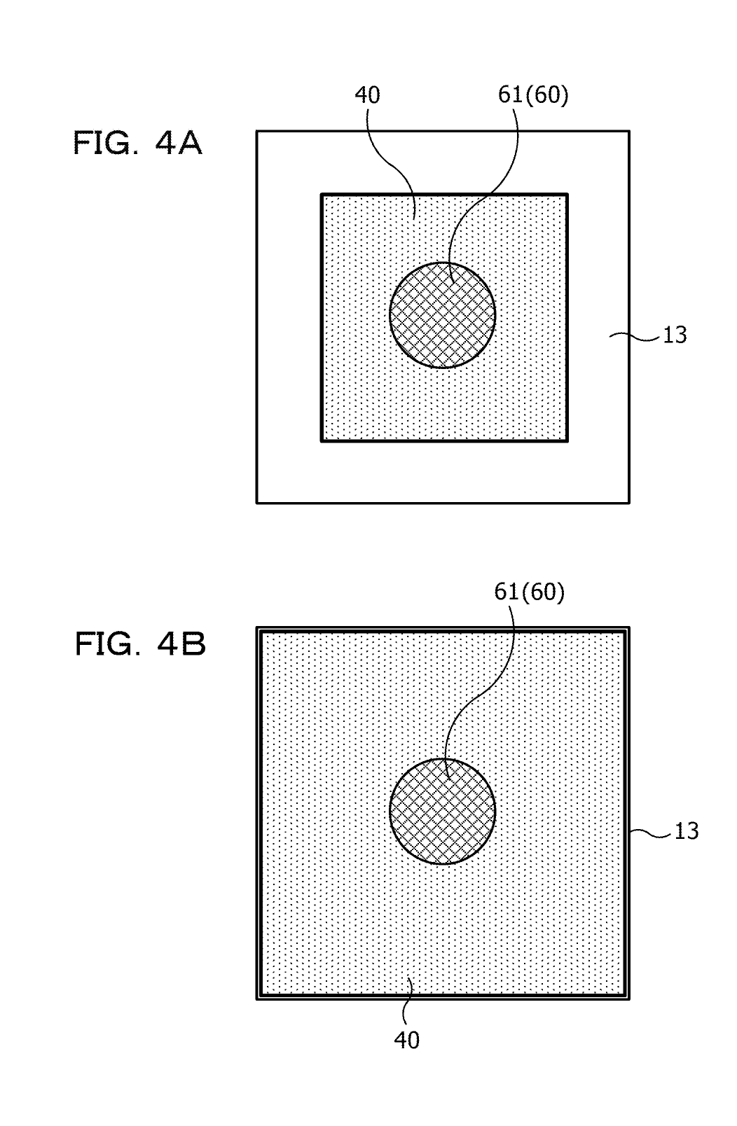

FIGS. 4A and 4B are diagrams depicting another example of an arrangement of a conductor layer on an electrode of a capacitor and a conductor via coupled to the conductor layer. FIG. 4A and FIG. 4B each schematically depict the planar arrangement of the electrode, the conductor layer on the electrode, and the lower end of the conductor via coupled to the conductor layer.

For example, as depicted in FIG. 4A, the conductor layer 40 may be disposed at a planar size smaller than that of the electrode 13 and in a rectangular shape in the planar view, on the electrode 13 of the capacitor 10. The lower end 61 of the conductor via 60 is coupled to a portion of the conductor layer 40 as depicted in FIG. 4A. The reduction of the resistance component and the reduction thereby of the impedance are facilitated also in the case where the lower end 61 of the conductor via 60 is coupled to the electrode 13 through the conductor layer 40 that has the planar size and the planar shape as depicted in FIG. 4A, compared to the case where the lower end 61 is directly coupled to the electrode 13 without the conductor layer 40 present therebetween.

Moreover, for example, as depicted in FIG. 4B, the conductor layer 40 may be disposed on the overall electrode 13 of the capacitor 10. In addition, in FIG. 4B, for convenience, the conductor layer 40 is depicted to be somewhat smaller than the electrode 13. The lower end 61 of the conductor via 60 is coupled to the portion of the conductor layer 40 as depicted in FIG. 4B. The reduction of the resistance component and the reduction thereby of the impedance are facilitated also in the case where the lower end 61 of the conductor via 60 is coupled to the electrode 13 through the conductor layer 40 as depicted in FIG. 4B, compared to the case where the lower end 61 is directly coupled to the electrode 13 without the conductor layer 40 present therebetween.

The configuration and the properties of the circuit substrate according to the first embodiment will further be described.

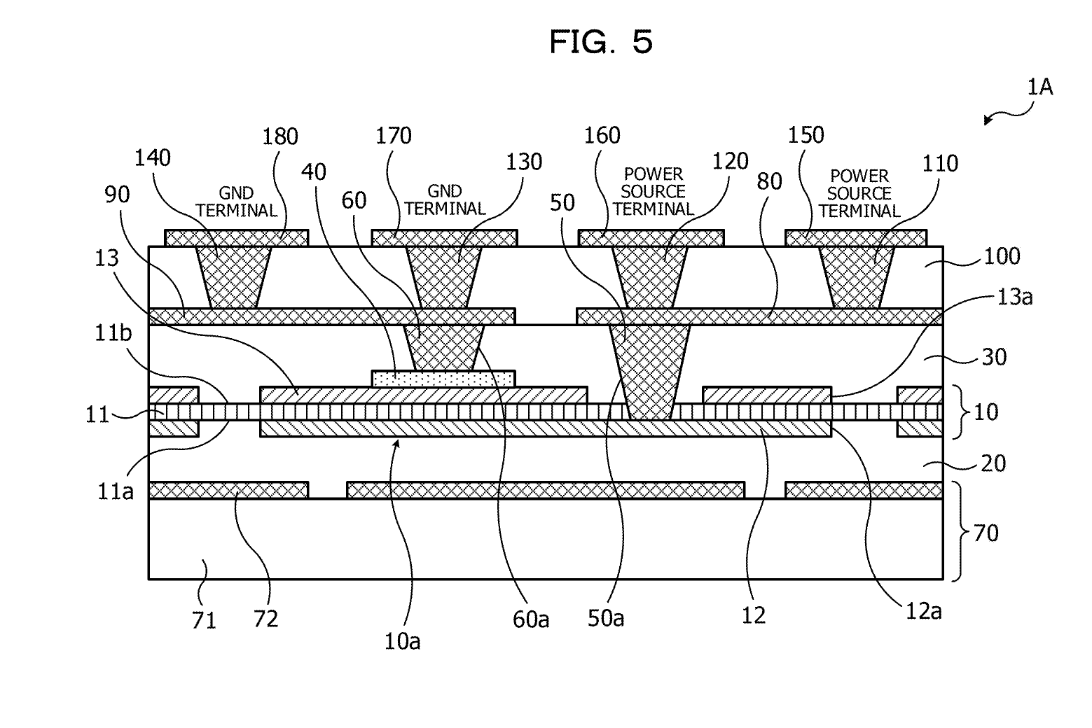

FIG. 5 is a diagram depicting an example of a configuration of a circuit substrate. FIG. 5 schematically depicts a cross-sectional view of the essential portion of an example of the circuit substrate.

A circuit substrate 1A depicted in FIG. 5 is an example of the configuration of the circuit substrate that employs the configuration of the circuit substrate 1 as depicted in FIG. 1 above. The circuit substrate 1A includes the capacitor 10, the conductor layer 40 disposed on the electrode 13 of the capacitor 10, the insulating layer 20 and the insulating layer 30 that cover these components, and the conductor via 50 and the conductor via 60 that are disposed in the insulating layer 30. The circuit substrate 1A further includes a base substrate 70 that is disposed on the side opposite to that of the capacitor 10, of the insulating layer 20. The circuit substrate 1A also includes a wire 80 and a wire 90 that are disposed on the side opposite to that of the capacitor 10, of the insulating layer 30. An insulating layer 100, conductor vias 110, 120, 130, and 140, and wires 150, 160, 170, and 180 are further disposed on the insulating layer 30.

The base substrate 70 includes insulating layer(s) that is/are one layer or plural layers, and wires in one layer or plural layers. FIG. 5 depicts the base substrate 70 that includes an insulating layer 71 and a wire 72 disposed on the surface of the insulating layer 71. The capacitor 10 is stacked with its side to the electrode 12, facing toward the base substrate 70, through the insulating layer 20.

The wire 80 and the wire 90 that are disposed on the insulating layer 30 are each set to have a given planar shape. The wire 80 is coupled to the conductor via 50 that is coupled to the electrode 12 of the capacitor 10. The wire 90 is coupled to the conductor via 60 that is coupled to the conductor layer 40 on the electrode 13 of the capacitor 10. Any one of various conductor materials, for example, a metal material such as Cu or the like is used in the wire 80 and the wire 90.

The insulating layer 100 is disposed on the insulating layer 30, and the wire 80 and the wire 90. A resin material such as an epoxy resin, a polyimide resin, or a bismaleimide triazine resin, or any one of these resin materials each including a fiber such as glass or the like, or cloth is usable in the insulating layer 100.

The conductor via 110 and the conductor via 120 penetrate the insulating layer 100 and are coupled to the wire 80. The conductor via 130 and the conductor via 140 penetrate the insulating layer 100 and are coupled to the wire 90. Any one of various conductor materials, for example, a metal material such as Cu or the like is used in each of the conductor vias 110, 120, 130, and 140.

The wires 150, 160, 170, and 180 are each set to have a given planar shape. The wire 150 is coupled to the conductor via 110. The wire 160 is coupled to the conductor via 120. The wire 170 is coupled to the conductor via 130. The wire 180 is coupled to the conductor via 140.

For example, the wires 150, 160, 170, and 180 are each used as a terminal for external coupling of the circuit substrate 1A. The wire 150 and the wire 160 electrically coupled to the electrode 12 of the capacitor 10, that uses therein the conductor material whose electric resistivity is relatively low such as Cu, through the conductor via 50, the wire 80, the conductor via 110, and the conductor via 120 are used as power source terminals. The wire 170 and the wire 180 electrically coupled to the electrode 13 of the capacitor 10, that uses therein the conductor material whose electric resistivity is relatively high such as Ni, through the conductor via 60, the wire 90, the conductor via 130, and the conductor via 140 are used as GND terminals.

The result of an evaluation of the properties of the circuit substrate 1A will be described next.

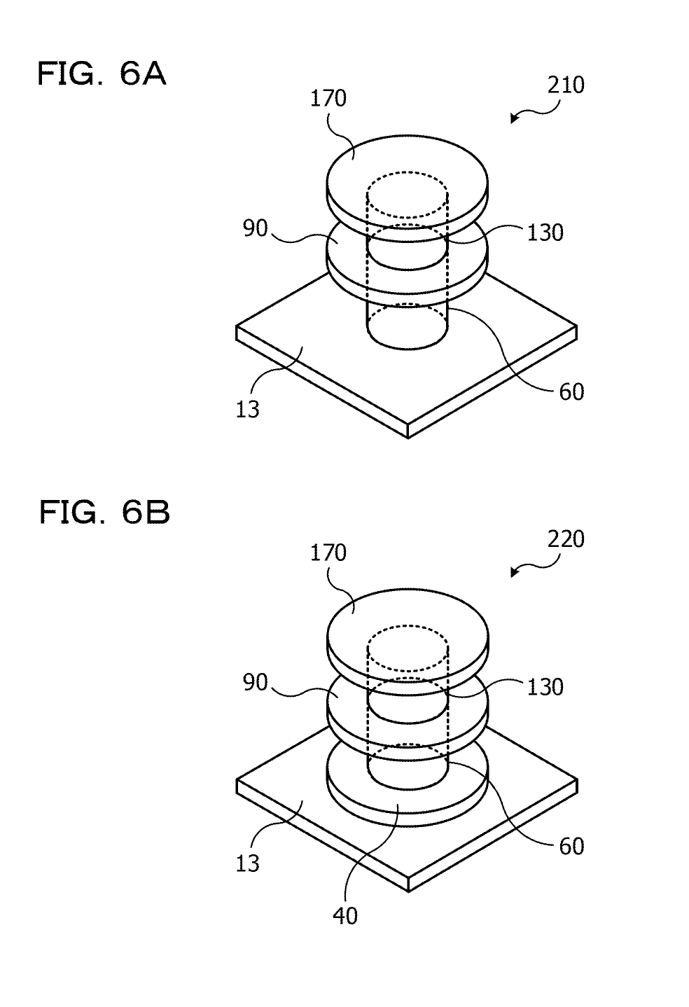

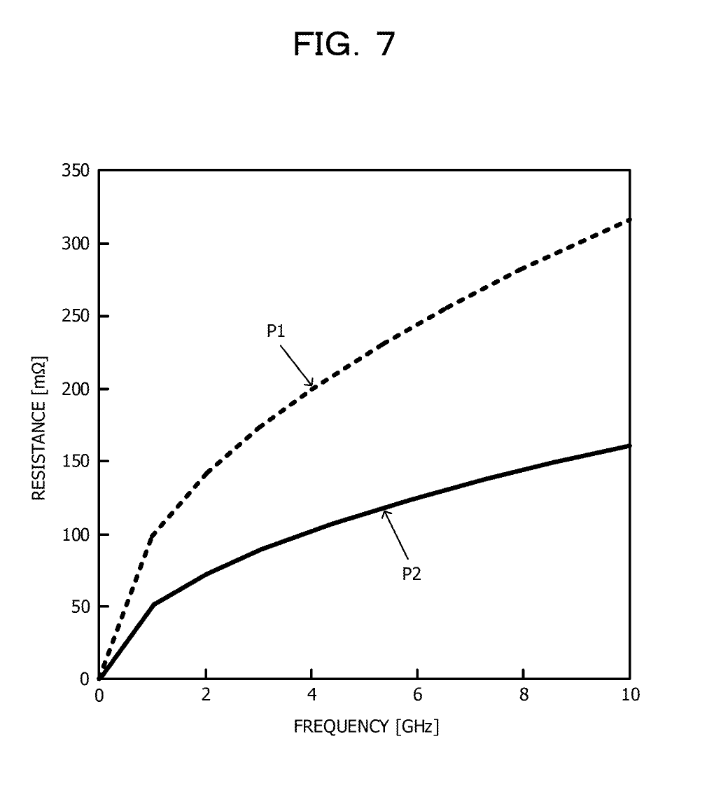

FIGS. 6A and 6B and FIG. 7 are diagrams explaining an evaluation of a resistance component. FIG. 6A and FIG. 6B each depict a model used for an electromagnetic field simulation of the relation between the frequency and the resistance of a transmission signal in the electrode of the capacitor, and the conductor via and the wire that were electrically coupled to the electrode (a three-dimensional electromagnetic field simulation). FIG. 7 depicts the result of the electromagnetic field simulation.

For comparison, FIG. 6A depicts a model 210 that did not include the conductor layer 40 and FIG. 6B depicts a model 220 that included the conductor layer 40. The model 210 not including the conductor layer 40, depicted in FIG. 6A therefore included the electrode 13 of the capacitor 10, and the conductor via 60, the wire 90, the conductor via 130, and the wire 170 that were electrically coupled to the electrode 13. The model 220 including the conductor layer 40, depicted in FIG. 6B included the electrode 13 of the capacitor 10, the conductor layer 40 disposed on the electrode 13, and the conductor via 60, the wire 90, the conductor via 130, and the wire 170 that were electrically coupled to the electrode 13.

In the electromagnetic field simulation using the model 210 and the model 220, Ni was used as the conductor material of the electrode 13 of the capacitor 10 and Cu was used as the conductor material of the conductor layer 40, the conductor via 60, the wire 90, the conductor via 130, and the wire 170. The electrode 13 of the capacitor 10 was set to have a planar size of 500 μm×500 μm and a thickness of 30 μm. The conductor layer 40 was set to have a circular planar shape whose diameter was 100 μm and a thickness of 10 μm. The conductor via 60 was set to have a cylindrical shape whose diameter was 50 μm and a height of 100 μm in the model 210 and a height of 90 μm in the model 220 (100 μm in total including that of the conductor layer 40). The wire 90 was set to have a circular planar shape whose diameter was 100 μm and a thickness of 10 μm. The conductor via 130 was set to have a cylindrical shape whose diameter was 50 μm and a height of 100 μm. The wire 170 was set to have a circular planar shape whose diameter was 100 μm and a thickness of 10 μm.

Using the model 210 and the model 220, the relation between the frequency [GHz] of a transmission signal and the resistance [mΩ], between the lower face of the electrode 13 of Ni and the upper face of the wire 170 of Cu was evaluated using the electromagnetic field simulation. The result of this is depicted in FIG. 7.

In FIG. 7, a relation P1 indicates a result obtained for the model 210 and a relation P2 indicates a result obtained for the model 220.

From FIG. 7, the resistance was increased as the frequency of the transmission signal was increased. In the model 220 having the conductor layer 40 of Cu disposed therein between the electrode 13 of Ni of the capacitor 10 and the conductor via 60 of Cu, an effect that the resistance was reduced was recognized compared to the model 210 not having the conductor layer 40 disposed therein. In addition, in the model 220, the effect of reducing the resistance was enhanced than that of the model 210 as the frequency of the transmission signal was increased.

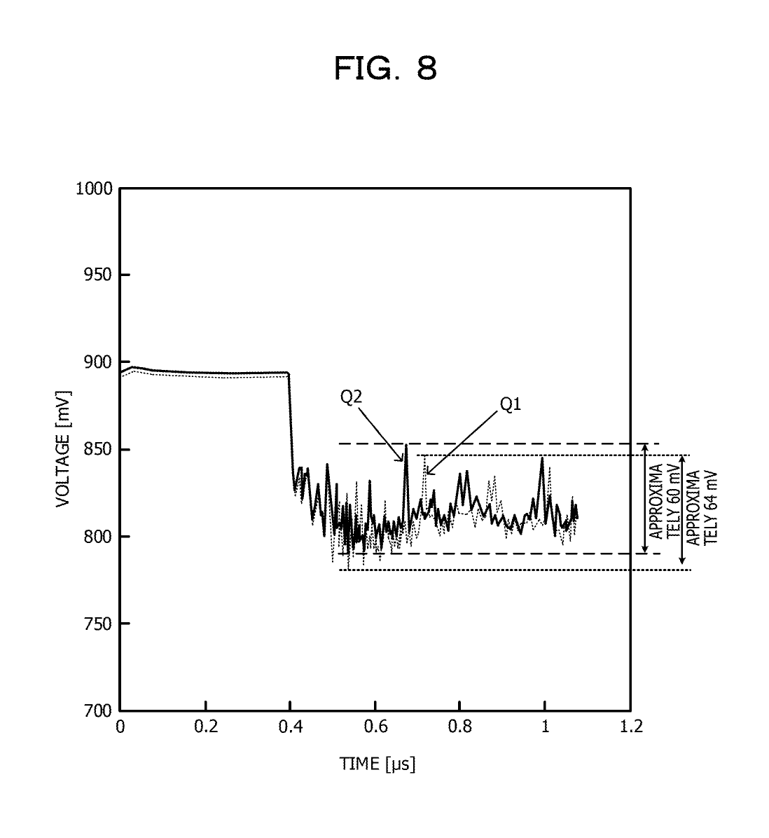

FIG. 8 is a graph explaining an evaluation of a power source noise. FIG. 8 depicts variation (variation over time) of a voltage [mV] to time [μs], of an output signal output when a noise was inserted into a power source input into the circuit substrate.

A relation Q1 in FIG. 8 indicates the variation over time of the voltage of the output signal of the circuit substrate not having the conductor layer 40 of Cu disposed therein between the electrode 13 of Ni of the capacitor 10 and the conductor via 60 of Cu. A relation Q2 in FIG. 8 indicates the variation over time of the voltage of the output signal of the circuit substrate 1A having the conductor layer 40 of Cu disposed therein between the electrode 13 of Ni of the capacitor 10 and the conductor via 60 of Cu.

From FIG. 8, the fluctuation width of the voltage of the output signal of the circuit substrate not having the conductor layer 40 disposed therein was approximately 64 mV while the fluctuation width of the voltage of the output signal of the circuit substrate 1A having the conductor layer 40 disposed therein was approximately 60 mV. The effect of reducing the power source noise by approximately 7% was recognized because of the fact that the conductor layer 40 was disposed therein.

As above, as to the circuit substrate 1A, the resistance component was reduced, the impedance was thereby reduced, and the effect of reducing the power source noise was enhanced because of the fact that the conductor layer 40 of Cu was disposed between the electrode 13 of Ni of the capacitor 10 and the conductor via 60 of Cu. The circuit substrate 1A having an excellent power source noise reduction effect was realized by the above configuration.

The result of an evaluation of an influence exerted on the properties by the size of the conductor layer 40 disposed between the electrode 13 of the capacitor 10 and the conductor via 60 will be described next.

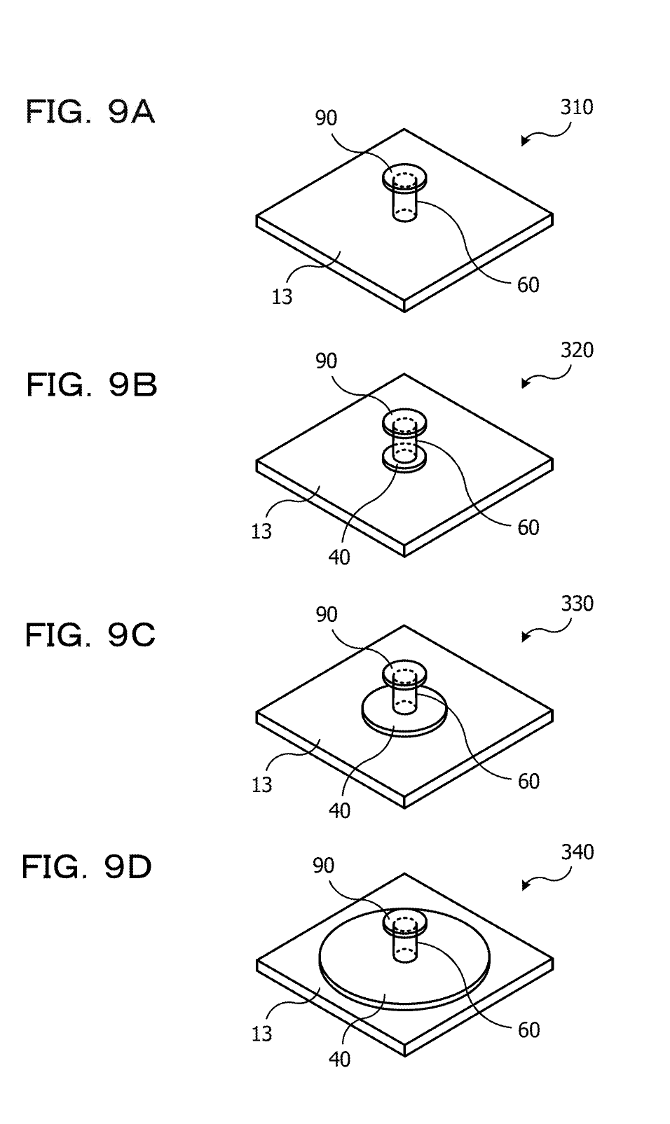

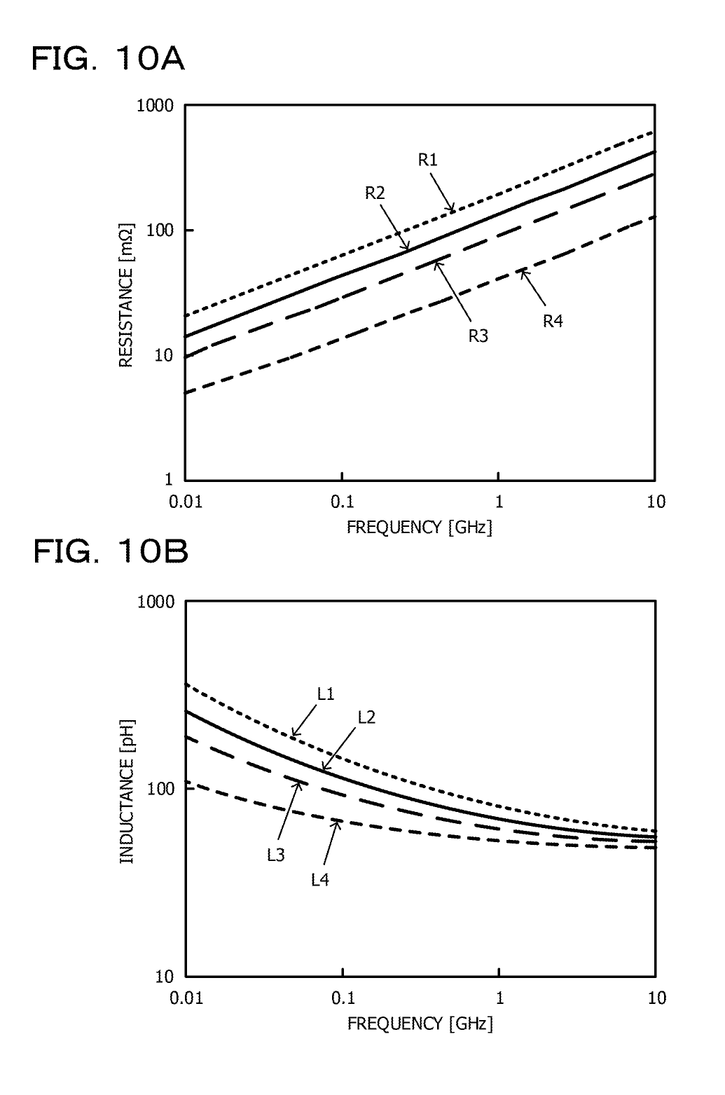

FIGS. 9A to 9D and FIGS. 10A and 10B are diagrams explaining an evaluation of an influence exerted on properties by an area of a conductor layer. FIG. 9A to FIG. 9D each depict a model used in the electromagnetic field simulation of the relation between the frequency of a transmission signal, and the resistance and the impedance in the electrode of the capacitor, and the conductor via and the wire that were electrically coupled to the electrode. FIG. 10A and FIG. 10B each depict the result of the electromagnetic field simulation.

For comparison, FIG. 9A depicts a model 310 that did not include the conductor layer 40, and FIG. 9B, FIG. 9C, and FIG. 9D respectively depict a model 320, a model 330, and a model 340 that each included the conductor layer 40. The model 310 not including the conductor layer 40, depicted in FIG. 9A therefore included the electrode 13 of the capacitor 10, and the conductor via 60 and the wire 90 that were electrically coupled to the electrode 13. The model 320, the model 330, and the model 340 each including the conductor layer 40, depicted in FIG. 9B, FIG. 9C, and FIG. 9D each included the electrode 13 of the capacitor 10, the conductor layer 40 disposed on the electrode 13, and the conductor via 60 and the wire 90 that were electrically coupled to the electrode 13.

In the electromagnetic field simulation using the model 310 and the models 320, 330, and 340, Ni was used as the conductor material of the electrode 13 of the capacitor 10 and Cu was used as the conductor material of the conductor layer 40, the conductor via 60, and the wire 90. The electrode 13 of the capacitor 10 was set to have a planar size of 500 μm×500 μm and a thickness of 30 μm. The conductor layer 40 was set to have a circular planar shape whose diameter was 100 μm in the model 320, a circular planar shape whose diameter was 200 μm in the model 330, and a circular planar shape whose diameter was 400 μm in the model 340, and a thickness of 10 μm in each of all these models. The conductor via 60 was set to have a cylindrical shape whose diameter was 50 μm and a height of 100 μm in the model 310 and a height of 90 μm (100 μm in total including that of the conductor layer 40) in each of the model 320, the model 330, and the model 340. The wire 90 was set to have a circular planar shape whose diameter was 100 μm, and a thickness of 10 μm.

Using the model 310 and the models 320, 330, and 340, the relation between the frequency [GHz] of a transmission signal, and the resistance [mΩ] and the inductance [pH], between the lower face of the electrode 13 of Ni and the upper face of the wire 90 of Cu was evaluated using the electromagnetic field simulation. The result of the evaluation of the relation between the frequency [GHz] and the resistance [mΩ] is depicted in FIG. 10A, and the result of the evaluation of the relation between the frequency [GHz] and the inductance [pH] is depicted in FIG. 10B.

In FIG. 10A, a relation R1 indicates the result obtained for the model 310, a relation R2 indicates the result obtained for the model 320, a relation R3 indicates the result obtained for the model 330, and a relation R4 indicates the result obtained for the model 340.

In FIG. 10B, a relation L1 indicates the result obtained for the model 310, a relation L2 indicates the result obtained for the model 320, a relation L3 indicates the result obtained for the model 330, and a relation L4 indicates the result obtained for the model 340.

From FIG. 10A, the resistance was increased as the frequency of the transmission signal was increased. As indicated by the relation R1 and the relations R2 to R4, the resistance was reduced when the conductor layer 40 of Cu was disposed between the electrode 13 of Ni of the capacitor 10 and the conductor via 60 of Cu, and, as indicated by the relations R2 to R4, the resistance was reduced as the planar size of the conductor layer 40 of Cu was increased.

From FIG. 10B, the inductance was reduced as the frequency of the transmission signal was increased. As indicated by the relation L1 and the relations L2 to L4, the inductance was reduced when the conductor layer 40 of Cu was disposed between the electrode 13 of Ni of the capacitor 10 and the conductor via 60 of Cu, and, as indicated by the relations L2 to L4, the inductance was reduced as the planar size of the conductor layer 40 of Cu was increased.

As above, the resistance component and the inductance component were reduced by disposing the conductor layer 40 of Cu between the electrode 13 of Ni of the capacitor 10 and the conductor via 60 of Cu, and the reduction effect therefor was enhanced as the planar size of the conductor layer 40 of Cu was increased. The circuit substrates 1 and 1A each presenting various properties may be realized by disposing the conductor layer 40 of Cu between the electrode 13 of Ni of the capacitor 10 and the conductor via 60 of Cu and adjusting the planar size of the conductor layer 40.

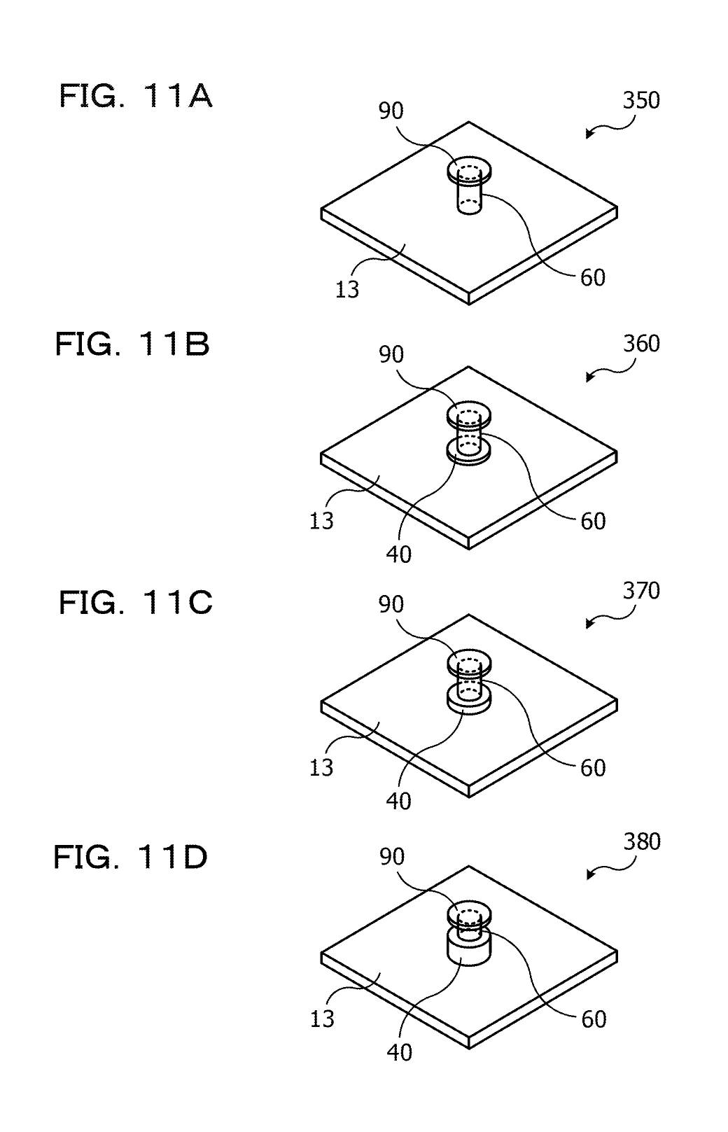

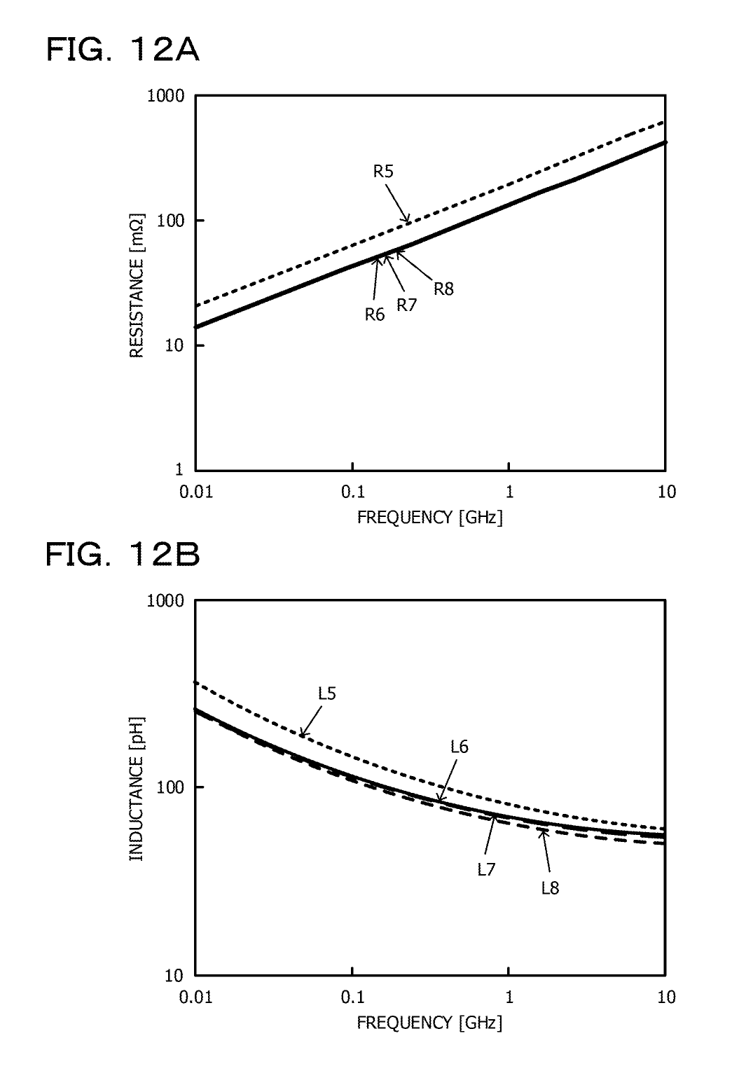

FIGS. 11A to 11D and FIGS. 12A and 12B are diagrams explaining an evaluation of an influence exerted on properties by a thickness of a conductor layer. FIG. 11A to FIG. 11D each depict a model used in the electromagnetic field simulation of the relation between the frequency of a transmission signal, and the resistance and the inductance in the electrode of the capacitor, and the conductor via and the wire that were electrically coupled to the electrode. FIG. 12A and FIG. 12B each depict the result of the electromagnetic field simulation.

For comparison, FIG. 11A depicts a model 350 that did not include the conductor layer 40, and FIG. 11B, FIG. 11C, and FIG. 11D respectively depict a model 360, a model 370, and a model 380 that each included the conductor layer 40. The model 350 not including the conductor layer 40, depicted in FIG. 11A therefore included the electrode 13 of the capacitor 10, the conductor via 60 and the wire 90 that were electrically coupled to the electrode 13. The model 360, the model 370, and the model 380 each including the conductor layer 40, depicted in FIG. 11B, FIG. 11C, and FIG. 11D each included the electrode 13 of the capacitor 10, the conductor layer 40 disposed on the electrode 13, and the conductor via 60 and the wire 90 that were electrically coupled to the electrode 13.

In the electromagnetic field simulation using the model 350 and the models 360, 370, and 380, Ni was used as the conductor material of the electrode 13 of the capacitor 10 and Cu was used as the conductor material of the conductor layer 40, the conductor via 60, and the wire 90. The electrode 13 of the capacitor 10 was set to have a planar size of 500 μm×500 μm and a thickness of 30 μm. The conductor layer 40 was set to have a thickness of 10 μm in the model 360, a thickness of 20 μm in the model 370, and a thickness of 50 μm in the model 380, and a circular planar shape whose diameter was 100 μm in all of these models. The conductor via 60 was set to have a cylindrical shape whose diameter was 50 μm and a height of 100 μm in the model 350 and a height of 100 μm in total including that of the conductor layer 40 in the model 360, the model 370, and the model 380. The wire 90 was set to have a circular planar shape whose diameter was 100 μm, and a thickness of 10 μm.

Using the model 350 and the models 360, 370, and 380 as above, the relation between the frequency [GHz] of a transmission signal, and the resistance [mΩ] and the inductance [pH], between the lower face of the electrode 13 of Ni and the upper face of the wire 90 of Cu was evaluated using the electromagnetic field simulation. The result of the evaluation of the relation between the frequency [GHz] and the resistance [mΩ] is depicted in FIG. 12A, and the result of the evaluation of the relation between the frequency [GHz] and the inductance [pH] is depicted in FIG. 12B.

In FIG. 12A, a relation R5 indicates the result obtained for the model 350, a relation R6 indicates the result obtained for the model 360, a relation R7 indicates the result obtained for the model 370, and a relation R8 indicates the result obtained for the model 380.

In FIG. 12B, a relation L5 indicates the result obtained for the model 350, a relation L6 indicates the result obtained for the model 360, a relation L7 indicates the result obtained for the model 370, and a relation L8 indicates the result obtained for the model 380.

From FIG. 12A, the resistance was increased as the frequency of the transmission signal was increased. As indicated by the relation R5 and the relations R6 to R8, the resistance was reduced when the conductor layer 40 of Cu was disposed between the electrode 13 of Ni of the capacitor 10 and the conductor via 60 of Cu. As indicated by the relations R6 to R8, however, no substantial difference in the reduction effect for the resistance was recognized even when the thickness of the conductor layer 40 of Cu was increased.

From FIG. 12B, the inductance was reduced as the frequency of the transmission signal was increased. As indicated by the relation L5 and the relations L6 to L8, the inductance was reduced when the conductor layer 40 of Cu was disposed between the electrode 13 of Ni of the capacitor 10 and the conductor via 60 of Cu. As indicated by the relations L6 to L8, however, no substantial difference in the reduction effect for the inductance was recognized even when the thickness of the conductor layer 40 of Cu was increased.

It may be stated that the influence exerted on the reduction of the resistance component and the inductance component by the thickness of the conductor layer 40 of Cu disposed between the electrode 13 of Ni of the capacitor 10 and the conductor via 60 of Cu is small as above compared to the influence exerted thereon by the planar size of the conductor layer 40.

### Second Embodiment

In this section, taking the example of the circuit substrate 1A having the above configuration, an example of a method for forming the circuit substrate 1A will be described as a second embodiment.

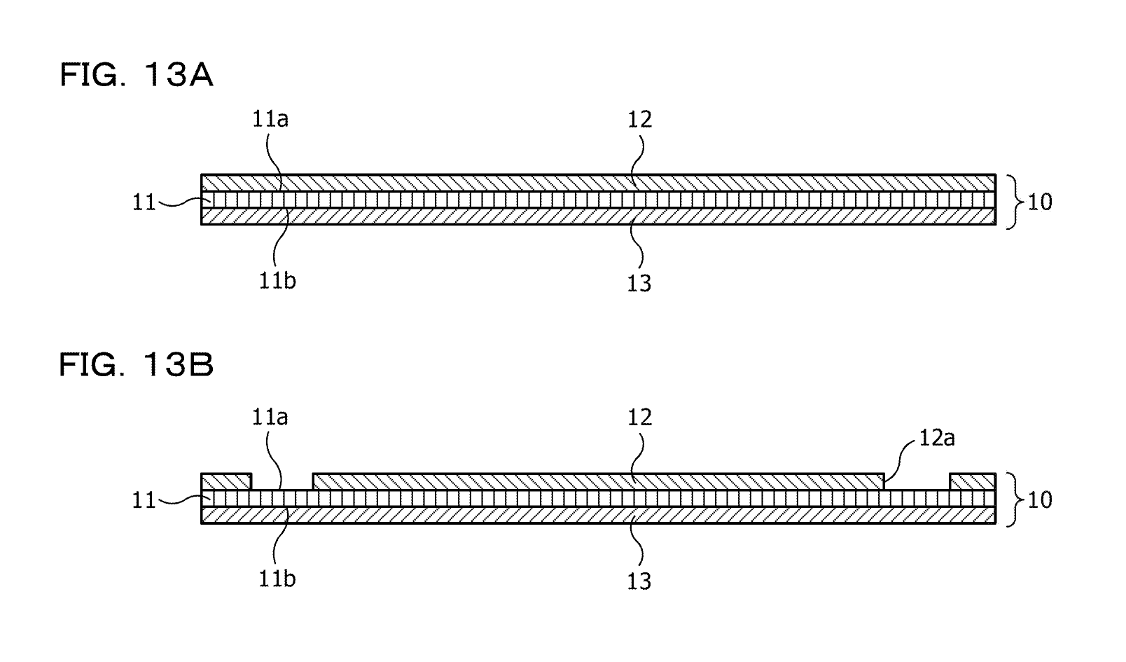

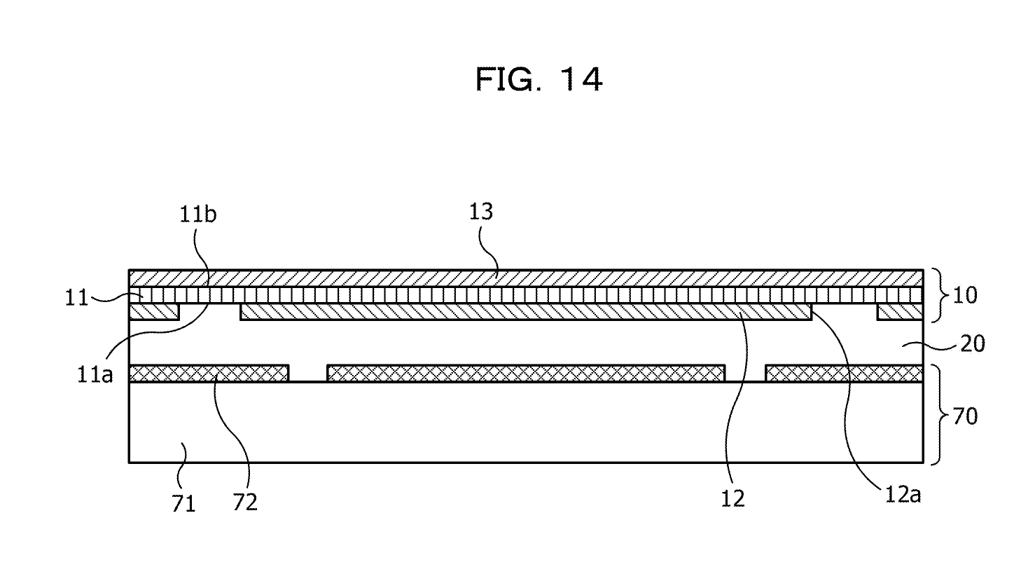

FIG. 13A to FIG. 20 are diagrams depicting an example of a circuit substrate forming method according to the second embodiment. FIG. 13A and FIG. 13B, and FIG. 14 to FIG. 20 each schematically depict a cross-sectional view of the essential portion of each process.

As depicted in FIG. 13A, a high dielectric material such as BTO to be the dielectric layer 11 is formed on a conductor material to be the electrode 13, and a conductor material to be the electrode 12 is formed on the high dielectric material. The capacitor 10 having the dielectric layer 11 sandwiched therein by the electrode 13 and the electrode 12 therebetween as depicted in FIG. 13A is thereby formed. For example, the thickness of the dielectric layer 11 is set to be 1 μm and the thickness of each of the electrode 13 and the electrode 12 is set to be 30 μm.

In the formation of the capacitor 10, the high dielectric material is formed on the electrode 13 by sintering and the electrode 12 is formed on the electrode 13 to cover the electrode 13. Because the high dielectric material is formed by sintering, it may be necessary to use a conductor material that is thermally stable against the temperature during the sintering, for the electrode 13 to be the base bed of the high dielectric material. For example, Ni is used in the electrode 13 to be the base bed taking into consideration the cost, the fabrication easiness, and the like in addition to the thermal stability. On the other hand, for example, Cu whose electric resistivity is low is used in the electrode 12 that is formed on the high dielectric material after the sintering of the high dielectric material because any restriction of the thermal stability as that on the electrode 13 is not imposed thereon.

As above, the formed capacitor 10 has the configuration using Cu that is the conductor material having the relatively low electric resistivity, in the one electrode 12 and using Ni that is the conductor material having the relatively high electric resistivity, in the other electrode 13.

As depicted in FIG. 13B, patterning is conducted next such that the electrode 12 of the capacitor 10 has a given pattern shape. This patterning is conducted by wet etching using a resist formed on the electrode 12 in the given pattern shape, as the mask. After the patterning, the resist is removed. The electrode 12 having the opening 12a disposed therein at a given position as depicted in FIG. 13B is formed by the patterning.

As depicted in FIG. 14, the capacitor 10 having the electrode 12 patterned thereon is next stacked on and integrated with the base substrate 70 through the insulating layer 20. At this time, the side of the electrode 12 of the capacitor 10 is caused to face the face that has the wire 72 of the base substrate 70 disposed thereon and, in the state where the insulating layer 20 using therein an epoxy resin or the like is present between this side and this face, thermal compression bonding is conducted for these. A structure (or a substrate) is thereby formed, that includes the capacitor 10 stacked on the base substrate 70 through the insulating layer 20, as depicted in FIG. 14.

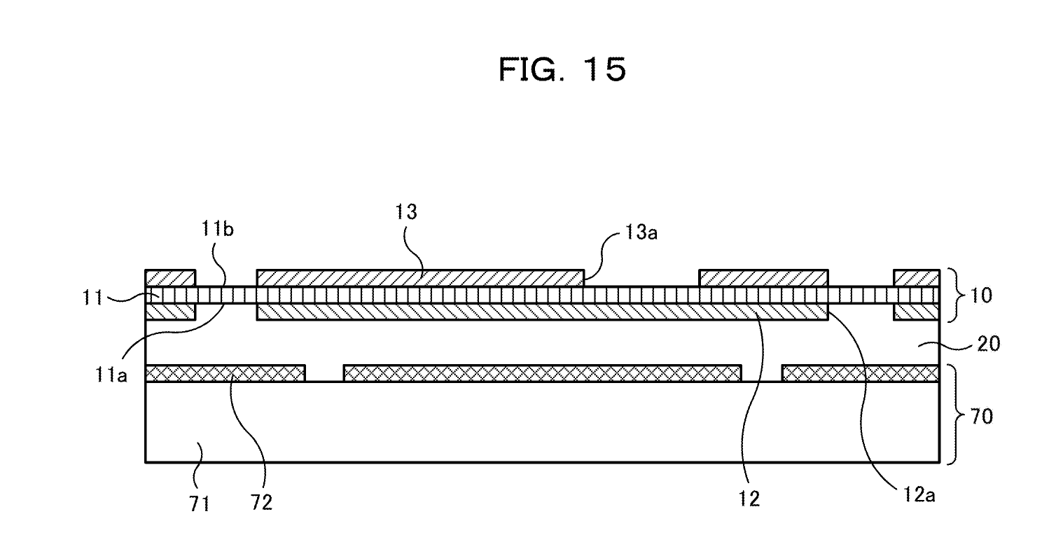

As depicted in FIG. 15, patterning is conducted next such that the electrode 13 of the capacitor 10 stacked on the base substrate 70 through the insulating layer 20 has a given pattern shape. This patterning is conducted by wet etching using a resist formed on the electrode 13 in the given pattern shape, as the mask. After the patterning, the resist is removed. The electrode 13 having the opening 13a disposed therein at a given position as depicted in FIG. 15 is formed by the patterning.

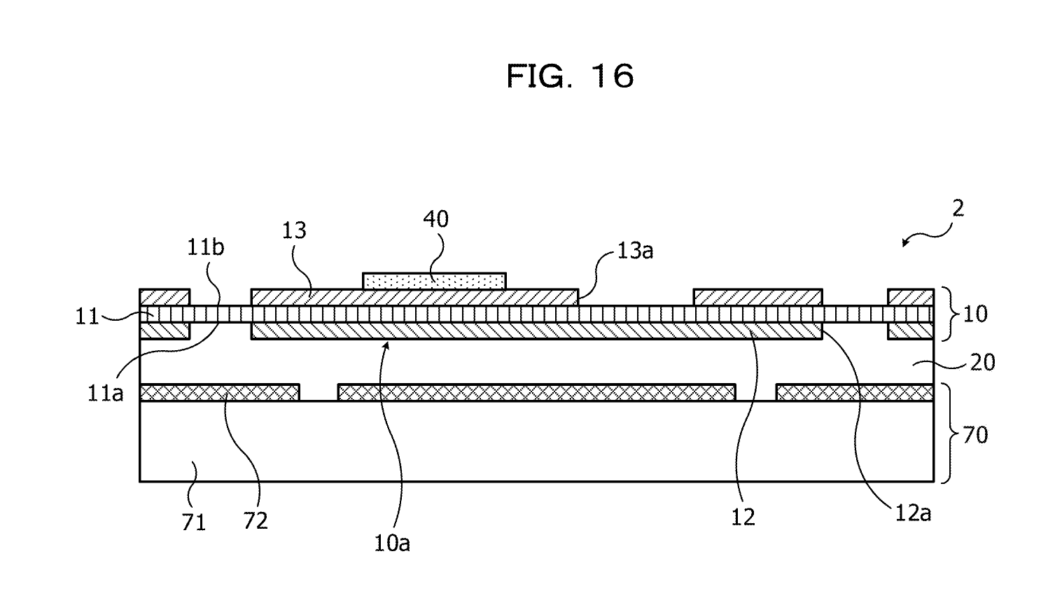

As depicted in FIG. 16, the conductor layer 40 is next formed on the electrode 13 of the capacitor 10. A conductor material having the electric resistivity lower than that of the electrode 13, for example, Cu is used in the conductor layer 40. The conductor layer 40 is formed by, for example, electroless copper plating and electrolytic copper plating. The conductor layer 40 may be formed using a sputtering method or the like, in addition to the plating method. The conductor layer 40 is formed to have a planar size that is larger than that of the lower end 61 of the conductor via 60 formed in the manner described later. The conductor layer 40 may be formed to have the shape, the planar size, and the thickness described in the above first embodiment (FIG. 3, FIGS. 4A and 4B, and FIGS. 6A to 12B).

A structure (or a substrate) 2 is thereby formed, that includes the substrate 10a including the capacitor 10 and the conductor layer 40 formed on the electrode 13 of the capacitor 10 as depicted in FIG. 16.

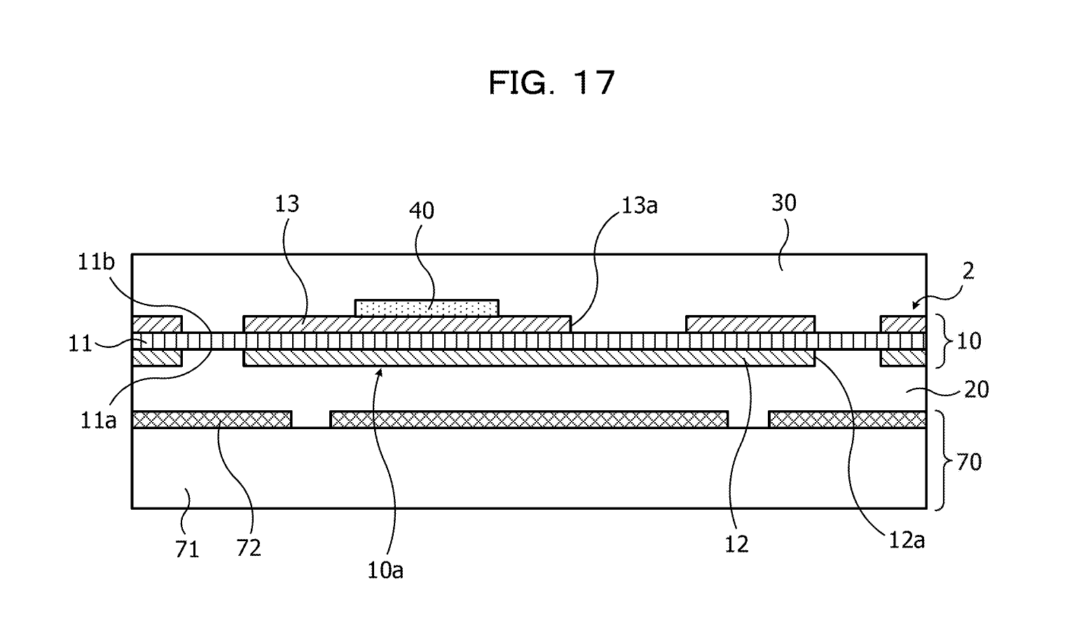

As depicted in FIG. 17, the insulating layer 30 using therein an epoxy resin or the like is next stacked by thermal compression bonding on the structure 2 (the substrate 10a thereof) for which fabrication is conducted up to the formation of the conductor layer 40 on the electrode 13 of the capacitor 10.

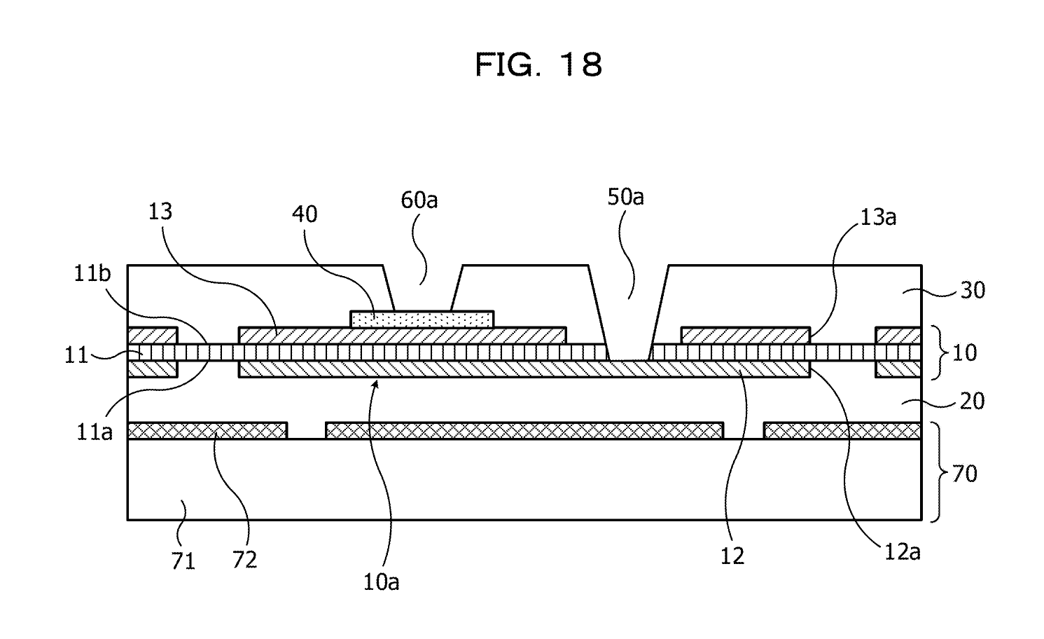

As depicted in FIG. 18, the opening 50a conducting to the electrode 12 of the capacitor 10 and the opening 60a conducting to a portion of the conductor layer 40 on the electrode 13 are next formed by laser processing.

Concerning the above, when the laser processing to form the opening 60a is conducted, a laser beam is directly applied to the conductor layer 40 and, on the other hand, no laser beam is directly applied to the electrode 13 of the capacitor 10. The thermal stress generated in the capacitor 10 by the application of the laser beam is alleviated. In addition, because the conductor layer 40 is formed on the electrode 13 of the capacitor 10, the film thickness of the insulating layer 30 in the region for the opening 60a to be formed becomes smaller than the film thickness of the insulating layer 30 in the other region. The time period for the region to have the opening 60a formed therein, of the insulating layer 30 to be exposed to the laser beam is therefore also reduced and the thermal stress generated in the capacitor 10 by the application of the laser beam is alleviated.

In the case where the conductor layer 40 is not disposed on the electrode 13 of the capacitor 10, the thermal stress generated in the capacitor 10 by the direct application of the laser beam to the electrode 13 may cause peeling off of the electrode 13 and the dielectric layer 11 from each other and the fabrication yield may be degraded. Disposing the conductor layer 40 on the electrode 13 of the capacitor 10 as above enables alleviation of the thermal stress caused by the application of the laser beam, suppression of any peeling off of the electrode 13 and the dielectric layer 11 from each other, and improvement of the fabrication yield.

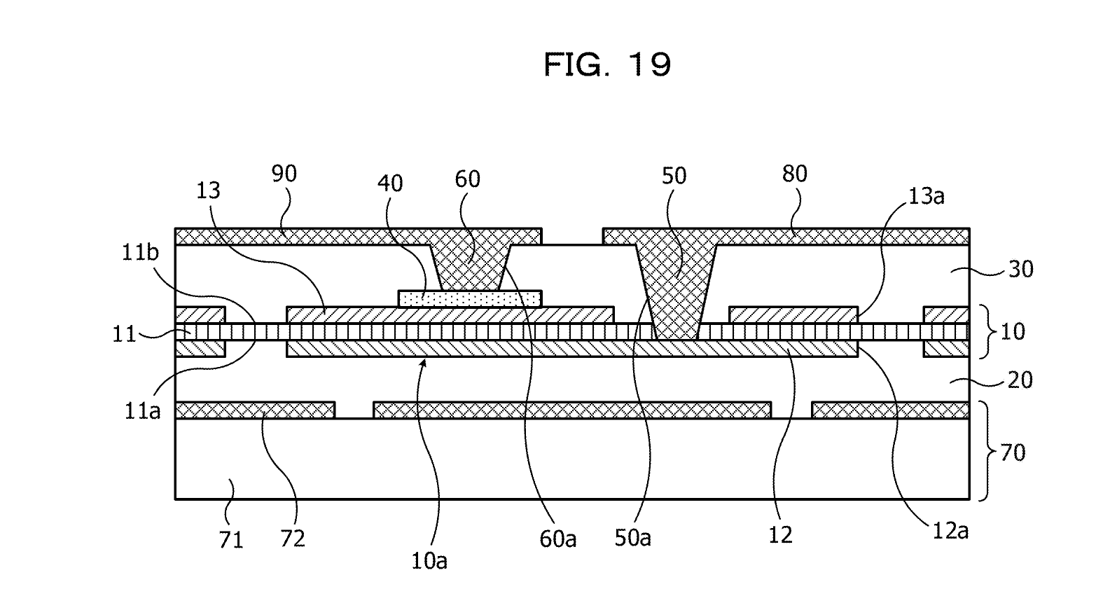

As depicted in FIG. 19, the conductor via 50 and the conductor via 60 are next formed respectively in the formed opening 50a and the formed opening 60a, and the wire 80 and the wire 90 are formed respectively on the conductor via 50 and the conductor via 60. A conductor material whose electric resistivity is lower than that of the electrode 13, for example, Cu is used in the conductor via 50, the conductor via 60, the wire 80, and the wire 90. The conductor via 50, the conductor via 60, the wire 80, and the wire 90 are formed by, for example, electroless copper plating and electrolytic copper plating. The conductor via 50 and the wire 80 coupled thereto are formed as one integrated component, and the conductor via 60 and the wire 90 coupled thereto are formed as one integrated component. The conductor via 50, the wire 80, the conductor via 60, and the wire 90 are formed undergoing the same plating process.

In addition, the example where the conductor via 50 and the conductor via 60 are formed as filled vias formed by filling the opening 50a and the opening 60a therewith is presented in this section while the conductor via 50 and the conductor via 60 may be formed as conformal vias.

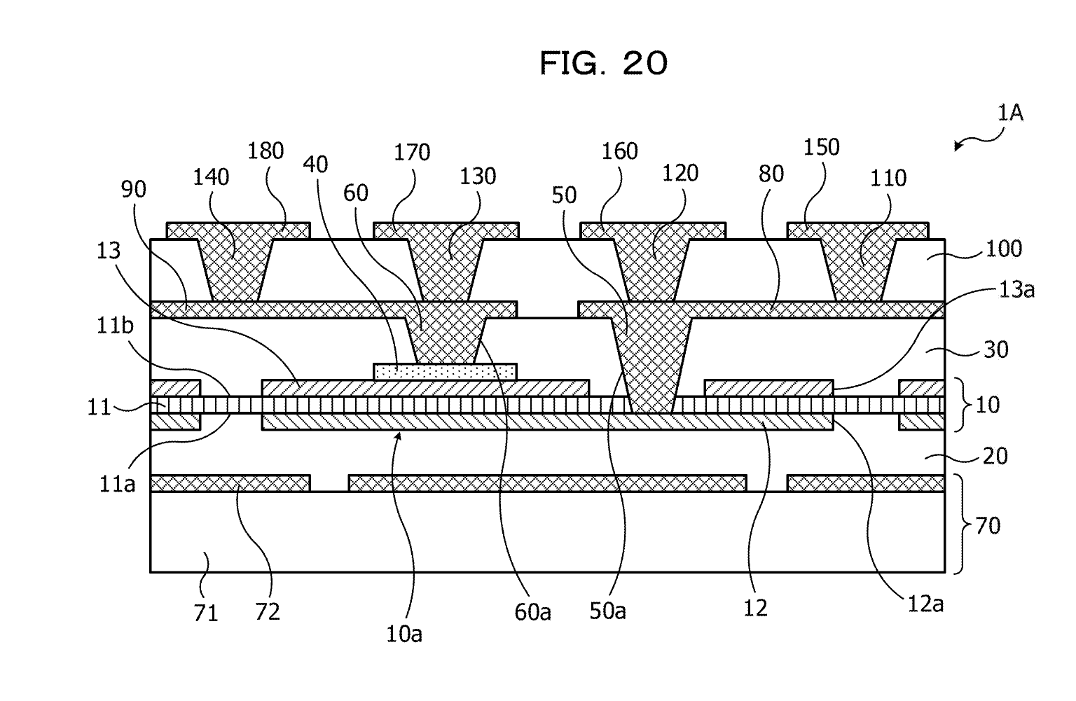

As depicted in FIG. 20, the insulating layer 100, the conductor vias 110, 120, 130, and 140, and the wires 150, 160, 170, and 180 are formed on the insulating layer 30 that has the conductor via 50, the conductor via 60, the wire 80, and the wire 90 formed thereon. The insulating layer 100, the conductor vias 110, 120, 130, and 140, and the wires 150, 160, 170, and 180 are formed in accordance with the example in FIG. 17 to FIG. 19. The insulating layer 100 using therein an epoxy resin or the like is therefore first stacked on the insulating layer 30 by thermal compression bonding. The conductor vias 110, 120, 130, and 140, and wires 150, 160, 170, and 180 are next formed by electroless copper plating and electrolytic copper plating in the openings formed by the laser processing in the insulating layer 100.

The circuit substrate 1A is formed in accordance with the method as depicted in FIG. 13A to FIG. 20.

In the circuit substrate 1A, the resistance component is reduced, the impedance is thereby reduced, and the reduction effect for the power source noise is therefore enhanced, by disposing the conductor layer 40 of Cu between the electrode 13 of Ni of the capacitor 10 and the conductor via 60 of Cu. In the formation of the circuit substrate 1A, at the formation process for the opening 50a and the opening 60a of the insulating layer 30 (FIG. 18), the laser application is conducted for the conductor layer 40 disposed on the electrode 13. The thermal stress caused by the laser application is therefore alleviated, any peeling off of the electrode 13 and the dielectric layer 11 from each other is suppressed, and improvement of the fabrication yield is facilitated. According to the above method, the circuit substrate 1A having an excellent power source noise reduction effect may be formed suppressing any degradation of the fabrication yield.

### Third Embodiment

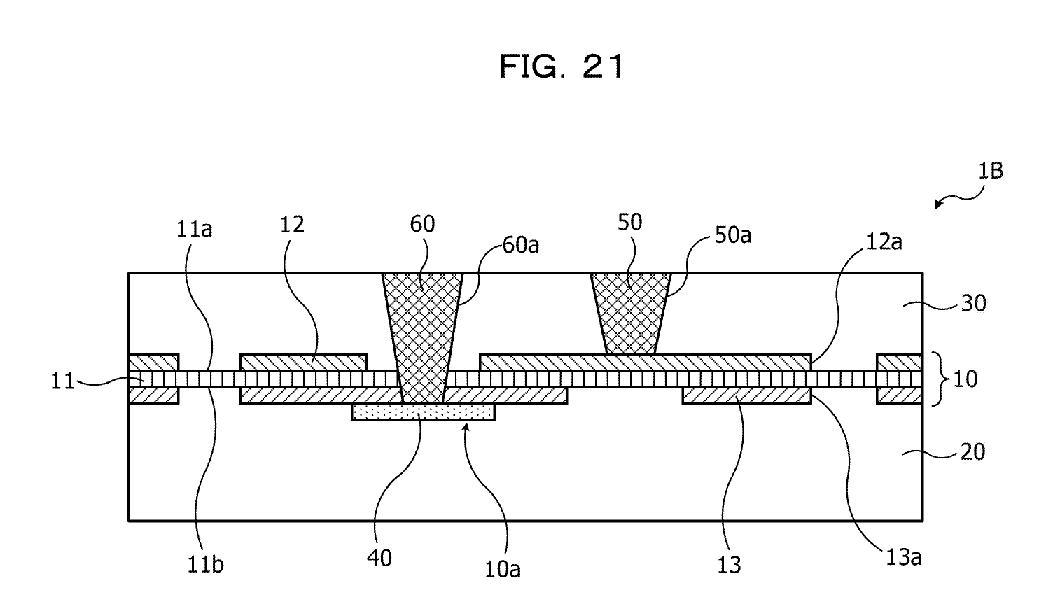

FIG. 21 is a diagram depicting an example of a circuit substrate according to a third embodiment. FIG. 21 schematically depicts a cross-sectional view of the essential portion of the example of the circuit substrate.

A circuit substrate 1B depicted in FIG. 21 has a structure for the side of the electrode 13 and the conductor layer 40, of the substrate 10a including the capacitor 10 and the conductor layer 40 disposed on the electrode 13 of the capacitor 10, to be covered by the insulating layer 20 and for the side of the electrode 12 thereof to be covered by the insulating layer 30.

In the circuit substrate 1B, the conductor via 50 penetrates the insulating layer 30 and is coupled to the electrode 12 of the capacitor 10. The conductor via 50 and the electrode 13 of the capacitor 10 are electrically isolated from each other. The conductor via 60 is disposed at the position corresponding to that of the opening 12a of the electrode 12 of the capacitor 10, penetrates the insulating layer 30, further penetrates the dielectric layer 11 and the electrode 13 of the capacitor 10, and is coupled to the conductor layer 40. The conductor via 60 and the electrode 12 of the capacitor 10 are electrically isolated from each other.

In the circuit substrate 1B, the opening 50a and the opening 60a to respectively have the conductor via 50 and the conductor via 60 formed therein are formed by, for example, laser processing. A conductor material such as Cu is disposed in each of the opening 50a and the opening 60a formed as above to form the conductor via 50 and the conductor via 60.

In addition, the conductor via 50 and the conductor via 60 may be formed as filled vias or may be formed as conformal vias. In the case where the conductor via 50 and the conductor via 60 are formed as conformal vias, a resin may fill the inside of each thereof.

In the circuit substrate 1B, the conductor via 60 is coupled to the electrode 13 of the capacitor 10 on its side face and is coupled to the conductor layer 40 disposed on the electrode 13 on the lower end 61. In the circuit substrate 1B, therefore, the resistance component between the conductor via 60 and the electrode 13 is reduced compared to the case where the conductor via 60 is coupled only to the electrode 13.

Even in the case where the conductor via 60 is disposed such that the conductor via 60 penetrates the dielectric layer 11 and the electrode 13 of the capacitor 10 to be coupled to the conductor layer 40 as in the circuit substrate 1B, the resistance component may be reduced, the impedance may thereby be reduced, and the reduction effect for the power source noise may be enhanced. The circuit substrate 1B having an excellent power source noise reduction effect may be realized by the above configuration.

### Fourth Embodiment

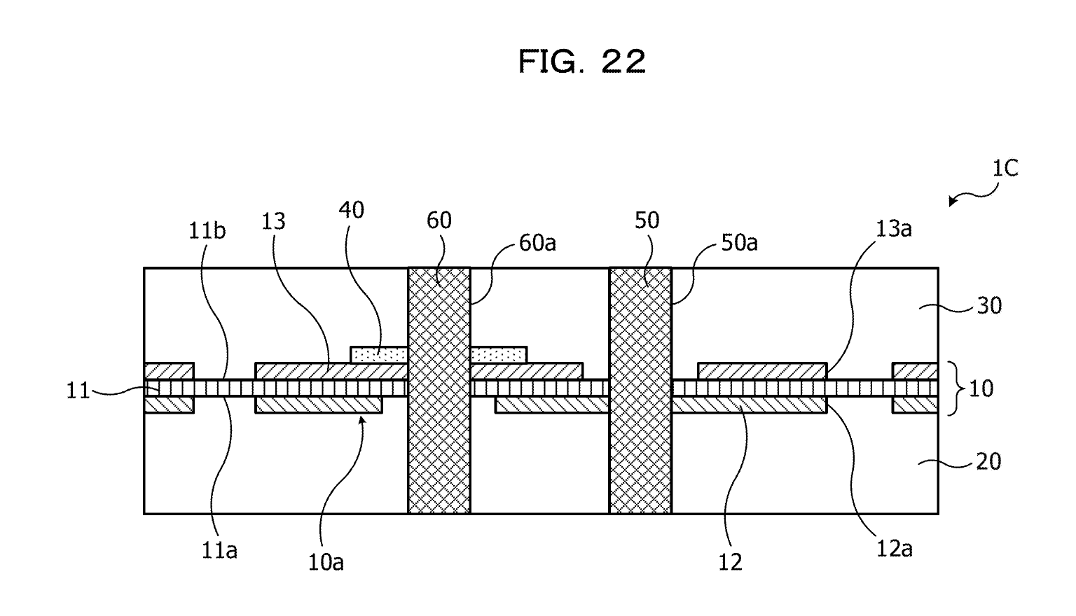

FIG. 22 is a diagram depicting an example of a circuit substrate according to a fourth embodiment. FIG. 22 schematically depicts a cross-sectional view of the essential portion of the example of the circuit substrate.

A circuit substrate 1C depicted in FIG. 22 has a structure for the conductor via 50 and the conductor via 60 to be disposed to penetrate the substrate 10a that includes the capacitor 10 and the conductor layer 40 disposed on the electrode 13 of the capacitor 10, and the insulating layer 20 and the insulating layer 30 that cover the substrate 10a.

In the circuit substrate 1C, the conductor via 50 is disposed at the position corresponding to that of the opening 13a of the electrode 13 of the capacitor 10, penetrates the insulating layer 30, also penetrates the dielectric layer 11 and the electrode 12 of the capacitor 10, and further penetrates the insulating layer 20. The conductor via 50 and the electrode 13 of the capacitor 10 are electrically isolated from each other. Moreover, the conductor via 60 is positioned at the position corresponding to that of the opening 12a of the electrode 12 of the capacitor 10, penetrates the insulating layer 30, also penetrates the conductor layer 40, and the electrode 13 and the dielectric layer 11 of the capacitor 10, and further penetrates the insulating layer 20. The conductor via 60 and the electrode 12 of the capacitor 10 are electrically isolated from each other.

In the circuit substrate 1C, the opening 50a and the opening 60a to respectively have the conductor via 50 and the conductor via 60 formed therein are formed by, for example, laser processing or drilling. A conductor material such as Cu is disposed in each of the opening 50a and the opening 60a formed as above, to form the conductor via 50 and the conductor via 60.

In addition, the conductor via 50 and the conductor via 60 may be formed as filled vias or may be formed as conformal vias. In the case where the conductor via 50 and the conductor via 60 are formed as conformal vias, a resin may fill the inside of each thereof.

In the circuit substrate 1C, the conductor via 60 is coupled to the electrode 13 of the capacitor 10 and the conductor layer 40 disposed on the electrode 13 on its side face. In the circuit substrate 1C, therefore, the resistance component between the conductor via 60 and the electrode 13 is reduced compared to the case where the conductor via 60 is coupled only to the electrode 13.

Even in the case where the conductor via 60 penetrates and is coupled to, the electrode 13 of the capacitor 10 and the conductor layer 40 as in the circuit substrate 1C, the resistance component may be reduced, the impedance may thereby be reduced, and the reduction effect for the power source noise may be enhanced. The circuit substrate 1C having an excellent power source noise reduction effect may be realized by the above configuration.

### Fifth Embodiment

The circuit substrates 1, 1A, 1B, and 1C as described above may each be mounted on any one of various electronic apparatuses. These circuit substrates may each be mounted on any one of various electronic apparatuses, for example, a computer (such as a personal computer, a super computer, or a server), a smartphone, a mobile phone, a tablet terminal, a sensor, a camera, an audio device, a measuring device, an inspecting device, or a producing device.

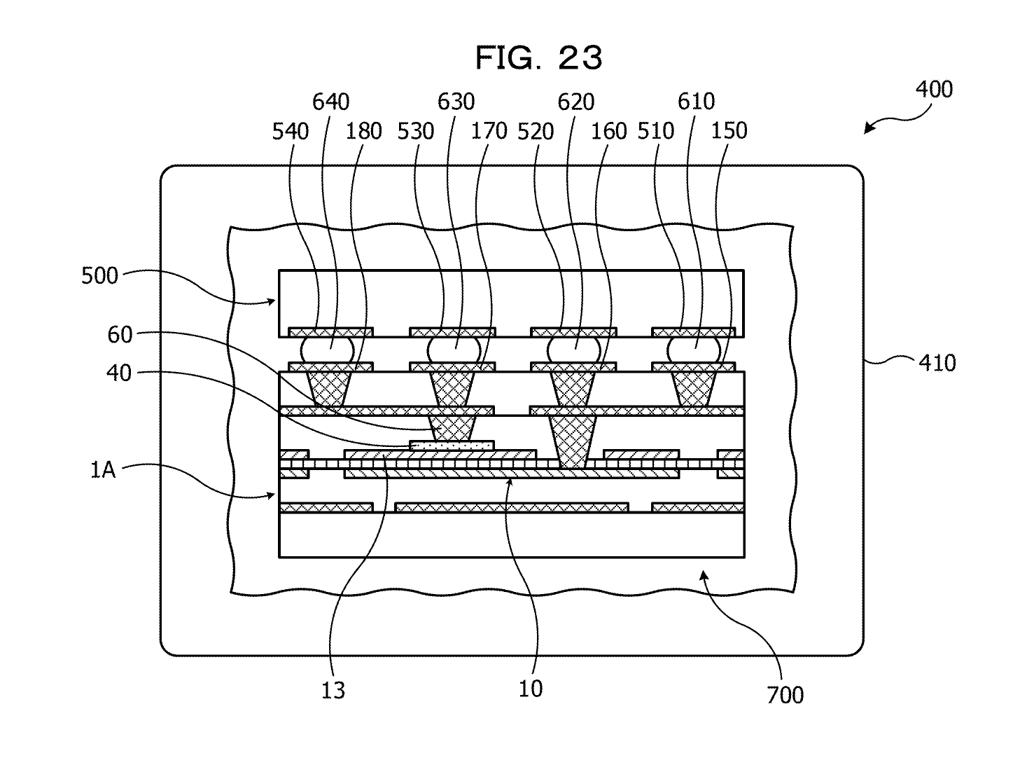

FIG. 23 is a diagram explaining an electronic apparatus according to a fifth embodiment. FIG. 23 schematically depicts the electronic apparatus.

As depicted in FIG. 23, for example, the circuit substrate 1A (FIG. 5) as described in the above first embodiment is mounted (incorporated) in the inside of a housing 410 of one of various electronic apparatuses 400. A semiconductor device 500 such as a semiconductor chip or a semiconductor package including a semiconductor chip is mounted on the circuit substrate 1A. The wires 150, 160, 170, and 180 used as terminals for external coupling, and terminals 510, 520, 530, and 540 of the semiconductor device 500 are respectively coupled to each other using bumps 610, 620, 630, and 640 such as those of solder. An electronic device 700 including the circuit substrate 1A and the semiconductor device 500 mounted thereon is mounted in the inside of the housing 410 of the electronic apparatus 400.

In addition, various electronic parts such as resistors, capacitors, and inductors may be mounted on the circuit substrate 1A in addition to the semiconductor device 500. Moreover, terminals for external coupling may be disposed also on the side of the base substrate 70 of the circuit substrate 1A and the electronic device 700 may further be mounted on another circuit substrate and, in this state, the electronic device 700 may be mounted on the electronic apparatus 400.

In the circuit substrate 1A, the conductor layer 40 using therein the material whose electric resistivity is relatively low is disposed between the electrode 13 using therein the material whose electric resistivity is relatively high of the capacitor 10 and the conductor via 60 using therein the material whose electric resistivity is relatively low. The resistance component may thereby be reduced, the impedance may thereby be reduced, and the reduction effect for the power source noise may be enhanced. The high performance electronic device 700 capable of causing the semiconductor device 500 mounted on the circuit substrate 1A to stably operate by suppressing any fluctuation of the power source voltage may be realized and the high performance electronic apparatus 400 having this electronic device 700 mounted thereon is realized.

The electronic apparatus 400 having the circuit substrate 1A and the electronic device 700 using the circuit substrate 1A, mounted thereon has been taken as the example in this embodiment while any one of various electronic apparatuses may similarly mount thereon the circuit substrate 1, 1B, or 1C and an electronic device that uses this circuit substrate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A circuit substrate comprising:
a first insulating layer;
a capacitor disposed over the first insulating layer, the capacitor including a dielectric layer, a first conductor layer disposed on a first face of the dielectric layer, and a second conductor layer disposed on a second face opposite to the first face of the dielectric layer and having an electric resistivity higher than that of the first conductor layer;
a third conductor layer disposed on a surface of the second conductor layer, the third conductor layer having an electric resistivity lower than that of the second conductor layer;
a second insulating layer covering the capacitor; and
a conductor via disposed in the second insulating layer, the conductor via being coupled to a portion of the third conductor layer.

2. The circuit substrate according to claim 1, wherein
the conductor via has an electric resistivity that is lower than that of the second conductor layer.

3. The circuit substrate according to claim 1, wherein
the second insulating layer covers the third conductor layer, and
the conductor via has one end face coupled to a portion of a surface of the third conductor layer.

4. The circuit substrate according to claim 1, wherein
the third conductor layer is disposed on a portion of a surface of the second conductor layer.

5. The circuit substrate according to claim 1, wherein
the conductor via is disposed in the second insulating layer and fills an opening that conducts to a portion of the third conductor layer.

6. A method for fabricating a circuit substrate, the method comprising:
forming a capacitor including a dielectric layer, a first conductor layer disposed on a first face of the dielectric layer, and a second conductor layer disposed on a second face opposite to the first face of the dielectric layer and having an electric resistivity higher than that of the first conductor layer;
arranging the capacitor over a substrate;
forming a third conductor layer having an electric resistivity lower than that of the second conductor layer, on a surface of the second conductor layer;
forming an insulating layer covering the capacitor; and
forming a conductor via coupled to a portion of the third conductor layer, in the insulating layer.
